(19) United States
(12) Patent Application Publication
(10) Pub. No.: US 2026/0058647 A1
(43) Pub. Date: Feb. 26, 2026

(54) TRANSISTOR MODULE, DRIVER FOR TRANSISTOR MODULE, CORRESPONDING SYSTEM AND METHOD

(71) Applicant: Infineon Technologies Austria AG, Villach (AT)

(72) Inventors: Daniele MIATTON, CARBONARA AL TICINO (IT); Karl Egil NORLING, Villach (AT); Anton MAUDER, Kolbermoor (DE); Daniel DOMES, Werl (DE)

(21) Appl. No.: 19/256,622

(22) Filed: Jul. 1, 2025

(30) Foreign Application Priority Data
Jul. 3, 2024 (DE) 102024206266.9

(51) Int. Cl. H03K 17/082

(52) U.S. Cl. CPC H03K 17/082

(57) ABSTRACT

A transistor module, driver for transistor module, corresponding system and method are provided. The transistor module comprises a transistor, an overcurrent protection circuit configured to detect an overcurrent condition of the transistor and to set the transistor to an overcurrent protection state in response to detecting the overcurrent condition, and a signaling circuit coupled to a control terminal of the transistor module and configured to modify a signal level at the control terminal in response to the overcurrent protection circuit detecting the overcurrent condition.

### RELATED APPLICATION

This application claims priority to German Patent Application No. 102024206266.9, filed on Jul. 3, 2024, entitled “TRANSISTOR MODULE, DRIVER FOR TRANSISTOR MODULE, SYSTEM AND METHOD”, which is incorporated by reference herein in its entirety.

### TECHNICAL FIELD

The present application relates to transistor modules, drivers for transistor modules, systems including drivers and transistor modules and corresponding methods.

### BACKGROUND

Power transistor-based switches are used in various applications to switch high currents or high voltages, for example to selectively couple a load to a power source like a supply voltage. One or more power transistors and other elements may be provided in a transistor module, which at least has two load terminals, for example source and drain, or collector and emitter terminals, and a control terminal, for example a gate terminal. A single power transistor may be provided, or several transistors may be provided, or for example a freewheeling diode may be provided for some transistor types. Power transistors may be made of a plurality of transistor cells coupled in series or in parallel to support high currents, for example several amperes, or high voltages.

In many applications, an overcurrent protection for such power transistors is required. An overcurrent condition may for example be caused by a short circuit where the power transistor in a switched-on state couples a very small load, for example only a few ohms, to a power supply. In such a short circuit case, the current flowing through the power transistor can become very large, leading for example to heating or damaging of the power transistor. Furthermore, also other parts of an electronic circuit may be damaged by the high current.

Therefore, various approaches for monitoring power transistors and taking countermeasures in case of an overcurrent have been developed. For example, for insulated gate bipolar transistor-based power transistors, a so-called desaturation detection (DESAT) has been employed, where a driver detects the overcurrent condition and then modifies the control signal to the transistor module to switch the transistor off. Such a detection by the driver may be comparatively slow. Therefore, in other approaches an overcurrent protection within the transistor module has been employed, for example by decoupling a power transistor of the transistor module from a control input of the transistor module and/or modifying a control signal of the power transistor inside the transistor module to switch the power transistor off or at least reduce the current through the power transistor. Also in such a case, it may be helpful that the driver can also recognize the overcurrent condition, to take additional measures like setting a gate control signal accordingly or to generate a fault signal to a system employing the power transistor and/or to a user.

### SUMMARY

According to an embodiment, a transistor module is provided, comprising: a transistor, wherein a first load node of the transistor is coupled to a first load terminal of the transistor module, a second load node of the transistor is coupled to a second load terminal of the transistor module, and wherein a control path is coupled between a control node of the transistor and a control terminal of the transistor module.

The transistor module further comprises an overcurrent protection circuit configured to detect an overcurrent condition of the transistor and to set the transistor to an overcurrent protection state in response to detecting the overcurrent condition, and
a signaling circuit coupled to the control terminal and configured to modify a signal level at the control terminal in response to the overcurrent protection circuit detecting the overcurrent condition.

In another embodiment, a driver for a transistor module is provided, comprising:
a driver output terminal configured to be coupled to a control terminal of the transistor module,
a driver circuit configured to generate a control signal to be output at the driver output terminal,
a sense terminal configured to be coupled to the control terminal of the transistor module, and
a detection circuit configured to detect an overcurrent condition of the transistor module based on a signal at the sense terminal.

According to another embodiment, a method is provided, comprising:
at a transistor module:
   detecting an overcurrent condition of a transistor of the transistor module,
   setting the transistor to an overcurrent protection state, and
at a driver coupled to a control terminal of the transistor module, detecting the overcurrent condition based on a signal level at the control terminal.

Corresponding systems are also provided.

The above summary is merely a brief overview over some embodiments and is not to be construed as limiting in any way.

### BRIEF DESCRIPTION OF THE DRAWINGS

FIG. 1 is a block diagram of a system according to an embodiment.

FIG. 2 is a flow chart illustrating a method according to an embodiment.

FIGS. 3A and 3B show systems according to various embodiments, and FIG. 3C illustrates example signals in the systems of FIGS. 3A and 3B.

FIG. 4A illustrates a system according to an embodiment, and FIGS. 4B and 4C illustrate example signals in the system of FIG. 4A.

FIG. 5A illustrates a system according to an embodiment, FIG. 5B illustrates example signals in the system of FIG. 5A, FIG. 5C illustrates a system according to an embodiment, and FIG. 5D illustrates example signals in the system of FIG. 5C.

FIG. 6 Illustrates a System According to an Embodiment.

FIG. 7 illustrates a system according to an embodiment.

FIG. 8 illustrates a multivibrator usable in some embodiments.

### DETAILED DESCRIPTION

In the following, various embodiments will be described in detail referring to the attached drawings. These embodiments are to be understood as examples only and are not to be construed as limiting. For example, while embodiments may be described as comprising specific features (for example elements, components, devices, acts, events), in other embodiments some of these features may be omitted or may be replaced by alternative features. In addition to the features explicitly shown and described, additional features may be provided, for example features conventionally used in transistor modules, drivers or systems and methods associated therewith.

Some embodiments relate to a transistor module. A transistor module is a device including one or more transistors, which may in particular act as switches. A transistor module may be provided as a single package, with a single housing or integrated on a single chip. For example, one or more chips may be provided in a single package.

In some embodiments, the transistor may be a power transistor designed for switching high currents or voltages, for example currents of several amperes or voltages of several 10 Volts or even 100 Volt or above. However, in other embodiments, the transistor may also be designed for lower voltages or currents, depending on the application. In some embodiments, the transistor is used as a transistor switch. The term “switch” in transistor switch refers to the fact that the transistor is intended to be used as a switch in either an on state or an off state, for example in contrast to transistors used in a linear range.

As already mentioned in the background, transistors may be made up of a plurality of transistor cells coupled in series or in parallel.

Transistors are described as comprising a control node, a first load node and a second load node. By applying a control signal to the control node, the transistor may be set to a desired state, for example switched on or off. A transistor is switched on or in an on state when it provides a low ohmic connection between its first and second load nodes, and is switched off when it essentially provides an electric isolation (apart from very small leakage currents which may occur in real implementations) between its first and second load nodes.

Various types of transistors may be used. Examples include field effect transistors (FETs), like metal oxide semiconductor field effect transistors (MOSFETs), insulated gate bipolar transistors (IGBTs) or bipolar junction transistors (BJTs). Transistors may be based on various semiconductor materials like silicon (Si), silicon carbide (SiC) or III-V compounds like gallium arsenide or gallium nitride.

In case of a field effect transistor or an insulated gate bipolar transistor, the control node is a gate node. Further, in case of a field effect transistor, the first load node is a drain node and the second load node is a source node. In case of an insulated gate bipolar transistor, the first load node is a collector node, and the second load node is an emitter node. In case of a bipolar junction transistor, the control node is a base node, the first load node is a collector node, and the second load node is an emitter node.

While transistor modules including a single transistor acting as a switch will be illustrated in the following as examples, a transistor module may also include more than one transistor, for example two transistors coupled in a half bridge or other configuration. In some embodiments, four or six transistor switches may be provided which may be arranged in pairs to form half bridge configurations, for example for driving different phases of an electric motor. Different transistors in a transistor module may be of the same type or different types. In this sense, the reference to “a transistor” or “a transistor switch” as used herein is to be construed as referring to one or more transistors, for example one or more transistor switches.

A control signal for controlling a transistor of a transistor module, for example for switching the transistor on or off, may be supplied by a driver. Such a driver may be provided separately to the transistor module, for example on a separate chip, in a separate package, or integrated with another electronic circuit.

In the figures, similar or corresponding elements are designated with the same reference numerals and will not be described repeatedly.

Variations, modifications and details described with respect to one of the embodiments are also applicable to other embodiments and will therefore not be discussed repeatedly. Furthermore, features from different embodiments may be combined unless noted otherwise.

Any signals shown in the drawings are to be seen as schematic examples only, as signals in real implementations may vary for example due to process, voltage or temperature variations and dimensioning of components.

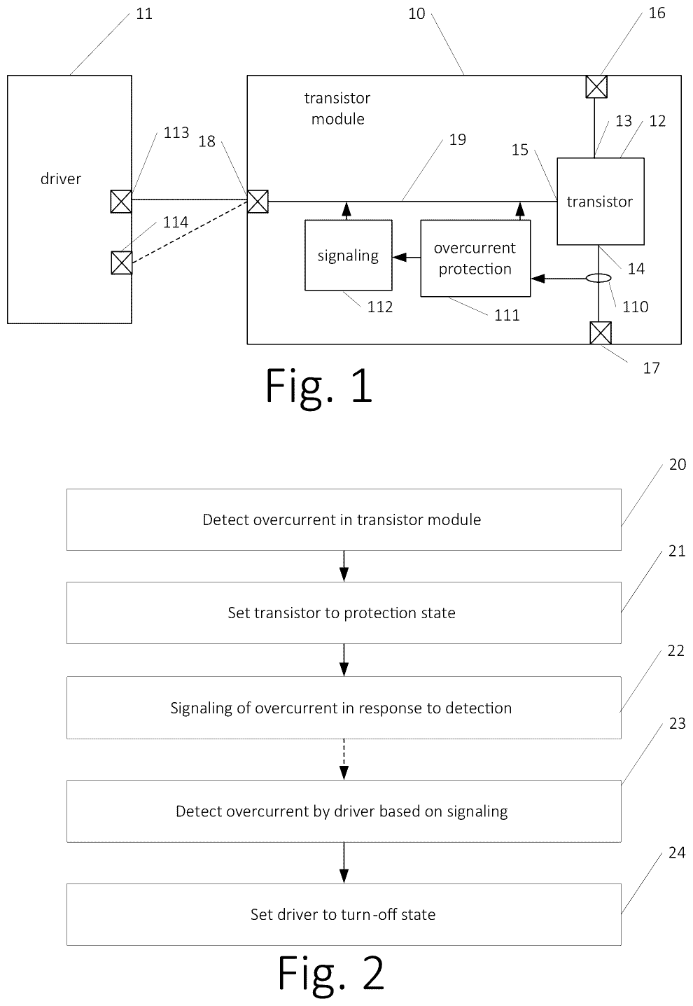

FIG. 1 illustrates a system according to an embodiment. The system of FIG. 1 comprises a transistor module 10 and a driver 11.

Transistor module 10 includes a transistor 12 having a first load node 13, a second load node 14 and a control node 15. In case of a field effect transistor, first load node 13 is a drain node, and second load node 14 is a source node. In case of an IGBT, first load node 13 is a collector node, and second load node 14 is an emitter node. While some embodiments described further below include a field effect transistor as an example, it is to be understood that also other transistor types like IGBTs or BJTs may be used.

First load node 13 is coupled to a first load terminal 16 of transistor module 10, and second load node 14 is coupled to a second load terminal 17 of transistor module 10. Control node 15 is coupled to a control terminal 18 of transistor module 10 via a control path 19, which in normal operation may provide a low ohmic connection between control terminal 18 and control node 15.

Driver 11 comprises a driver output terminal 113 coupled to control terminal 18. In some embodiments, a gate resistor may be provided between driver output terminal 113 and control terminal 18, in particular in case of a voltage-based driver. The gate resistor may be in part or completely monolithically integrated in the transistor 12. In case of a current-based driver where driver 11 outputs a predefined gate current level at driver output terminal 113, a gate resistor may be omitted.

Transistor module 10 includes an overcurrent protection circuit 111. Overcurrent protection circuit 111 is configured to detect an overcurrent condition of transistor 12 and to set the transistor 12 to an overcurrent protection state in response to detecting the overcurrent condition.

In some embodiments, a current measurement device 110 is provided which is configured to measure a current between load terminals 16, 17. For example, a sense resistor may be used, where a voltage drop across the sense resistor is indicative of the current. In other embodiments, a magnetic current measurement may be used, where a magnetic field generated by the current is measured using a magneto-sensitive device like a magneto-resistive sensor. In still other embodiments, a sense transistor may be used, which may be a scaled version of transistor 12.

Based on the measured current, for example when the measured current exceeds a predefined threshold, overcurrent protection circuit 111 detects an overcurrent condition. To set transistor 12 to an overcurrent protection state, overcurrent protection circuit 111 may for example interrupt control path 19 to isolate control terminal 18 from control node 15, and/or may modify the signal at control node 15 to at least partially switch transistor 12 off, thus reducing the load current. Switching at least partially off means that either the transistor is switched fully off, or it is set to reduce the saturation current for example in a linear range of transistor 12.

Furthermore, transistor module 10 includes a signaling circuit 112. When overcurrent protection circuit 111 detects an overcurrent condition, signaling circuit 112 generates a signal at control terminal 18 indicating the overcurrent condition. For example, a signal level at control terminal 18 may be set to a predefined level in response to overcurrent protection circuit 111 indicating the overcurrent condition, or a modulated signal may be generated by signaling circuit 112 at control terminal 18. Signaling circuit 112 includes at least some circuit components in addition to the components of overcurrent protection circuit 111.

By using control terminal 18 for this signaling, no additional terminal is required for signaling the overcurrent condition.

Driver 11 is configured to detect the overcurrent condition by identifying the signaling at control terminal 18 generated by signaling circuit 112. In response thereto, driver 11 may output a control signal to switch transistor 12 off, either by itself or controlled by some system entity like a system controller, which is notified by driver 11 of the detected fault. To detect the overcurrent condition, driver 11 may use a sense terminal, which may be the same terminal as driver output terminal 113 or may be an additional sense terminal 114. Sense terminal 114 may be a terminal also used for other purposes like a Miller clamp terminal. The sensing may include a voltage detection, current detection and/or comparing to a threshold value, as will be described using various examples in the following embodiments.

It should be noted that while in FIG. 1 for simplicity's sake driver 11 is shown as being coupled only to control terminal 18 of transistor module 10, driver 11 may additionally be coupled to a further terminal to provide a return path for the control signal. For example, driver 11 may be coupled to second load terminal 17. In other embodiments, an auxiliary terminal like an auxiliary source terminal or auxiliary emitter terminal (also referred to as Kelvin source or Kelvin emitter) may be provided at transistor module 10 and coupled to driver 11 to provide a return path. Examples will be shown in further embodiments below.

Overcurrent protection circuit 111 and signaling circuit 112 may be supplied with power based on a gate control signal at control terminal 18. For example, when the control signal is high, transistor 12 may be switched on, and the high voltage level may supply circuits 111, 112 with power. When transistor 12 is switched off and the voltage level at control terminal 18 is low, circuits 111, 112 are not supplied with power, but are also not needed as the transistor 12 is switched off and no overcurrent condition may occur.

FIG. 2 illustrates a method according to an embodiment. The method of FIG. 2 may be implemented in the system of FIG. 1, any of the systems discussed further below or in other systems. However, to avoid repetitions, the method of FIG. 2 will be described referring to FIG. 1 and the explanations given above with respect to FIG. 1.

At 20, the method comprises detecting an overcurrent through a transistor in a transistor module, i.e. the detection is performed within the transistor module. For example, as described with respect to FIG. 1 for current sensor 110 and overcurrent protection circuit 111, a current sensor may be used. In response to the detection, additionally at 21 in response to detecting the overcurrent the transistor is set to an overcurrent protection state, for example as described with respect to FIG. 1 for overcurrent protection circuit 111.

At 22 the transistor module signals the overcurrent in response to the detection at 20, for example by modifying a signal level at a gate control terminal of the transistor module.

The actions at 20 to 22 are performed within the transistor module.

At 23, a driver like driver 11 detects the overcurrent based on the signaling at 22. At 24, the driver may take additional countermeasures against the overcurrent like controlling a control signal to switch a transistor of the transistor module off, as also explained for driver 11 of FIG. 1.

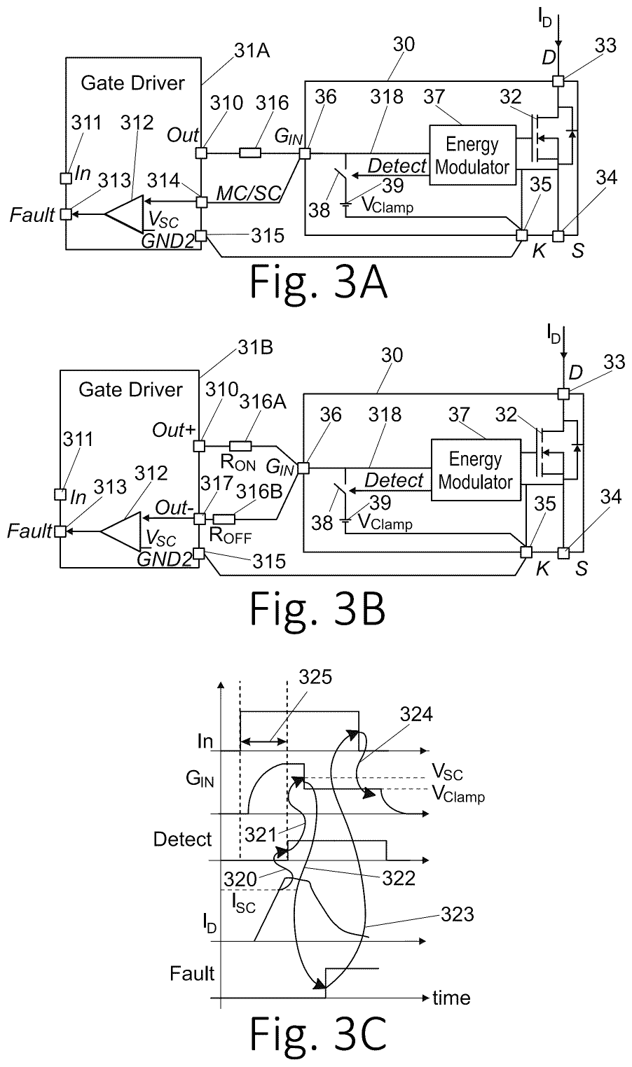

FIG. 3A illustrates a system according to a further embodiment, comprising a transistor module 30 and a driver (gate driver) 31A.

Transistor module 30 comprises a transistor 32, in the example shown a field-effect transistor having a body diode. A drain node of transistor 32 is coupled to a drain (D) terminal 33 of transistor module 30, and a source node of transistor 32 is coupled to a source(S) terminal 34 and an auxiliary source (K) terminal 35 of transistor module 30. A gate node of transistor 32 is coupled to a gate terminal 36 of transistor module 30 receiving a signal G_{IN} via a gate path 318. An energy modulator 37 is provided in gate path 318, which is an example for an overcurrent protection circuit. Energy modulator 37 measures a current I_{D} through transistor 32, for example as explained with reference to FIG. 1, and in case of an overcurrent condition modifies a signal level at a gate of transistor 32 to reduce the current. For example, energy modulator 37 may disconnect gate terminal 36 from transistor 32 and set the gate node of transistor 32 to a voltage which is at least partially switching off transistor 32. In some embodiments, energy modulator 37 may couple the gate node of transistor 32 to the source node of transistor 32, which essentially switches transistor 32 off by bringing the gate-source-voltage at least below the threshold voltage.

Furthermore, for signaling the detected overcurrent condition, energy modulator 37 controls a switch 38 to close in response to detecting the overcurrent condition. Switch 38 when closed couples gate terminal 36 to auxiliary source terminal 35 to set gate terminal 36 to a clamping voltage V_{clamp}, as symbolized by a voltage source 39. Switch 38 in combination with voltage source 39 is an example for a signaling circuit which signals the overcurrent condition at gate terminal 36, in this case by setting the voltage at gate terminal 36 to the clamping voltage V_{clamp}. V_{clamp} may be 90% or less of the voltage at gate terminal 36 during normal operation when transistor 32 is switched on, and may be 40% or more of this voltage, for example 75% or more. For example, to achieve this V_{clamp} is higher than a threshold voltage of the transistor 32, such as at least 110% of the threshold voltage, or at least 150% of the threshold voltage. A threshold for detection of the overcurrent condition at driver 31A may be set accordingly.

Driver 31A in normal operation provides a gate control signal at a driver output terminal 310, which is coupled to gate terminal 36 via a gate resistor 316. The gate control signal may be generated based on an input signal IN at an input terminal 311, which may be received for example from a system controller or any other entity. Any conventional gate driver circuit may be used for generating the gate control signal, for example circuits including a high side transistor switch and a low side transistor switch as explained further below.

Furthermore, a sense terminal 314, for example Miller clamp (MC/SC) terminal, is coupled to gate terminal 36 and serves to detect the overcurrent condition by detecting the voltage V_{clamp} at gate terminal 36. To this end, sense terminal 314 may be coupled to a first input of a comparator 312, and a reference voltage V_{SC} may be provided to a second input. Based on the comparison, assertion of V_{clamp} at gate terminal 36 may be detected. In particular, V_{clamp} is below the voltage usually used to control transistor 32 to be switched on, such that comparator 312 detects the overcurrent condition when the voltage at gate terminal 36 falls below V_{SC}. In case of the detection of the signaled overcurrent by comparator 312, a fault signal may be output by a fault terminal 313 to inform a management entity of a system including transistor module 30 and gate driver 31A like a system controller of the overcurrent condition. Furthermore, driver 31A may set the gate control signal at output terminal 310 to switch transistor 32 off, either by itself or in response to a corresponding signal IN sent by the management entity in response to receiving the fault signal.

A ground terminal 315 (GND2) is coupled to auxiliary source terminal 35 to provide a return path for the gate control signal.

FIG. 3B shows a variation of the system of FIG. 3A. The transistor module 30 is the same in both embodiments. In the system of FIG. 3B, instead of gate driver 31A of FIG. 3A gate driver 31B is provided. Gate driver 31B uses separate output terminals 310, 317 for outputting gate control signals for switching transistor 32 on and off, respectively. Driver output terminal 310 is used to output a gate control signal for switching transistor 32 on and is coupled to gate terminal 36 via a gate resistor 316A, and driver output terminal 317 is used to provide a gate control signal for switching transistor 32 off and is coupled to gate terminal 36 via a gate resistor 316B. Gate resistors 316A, 316B may have the same or different resistance values Rₒₙ, R_{off}, respectively.

In such a case, driver output terminal 317 may be used as sense terminal for detecting the clamp voltage V_{clamp}, as it is inactive when transistor 32 is switched on (and therefore an overcurrent condition may occur). The sensing using comparator 312 is the same as explained with reference to FIG. 3A.

Operation of the embodiments of FIGS. 3A and 3B is illustrated in a signal diagram in FIG. 3C, which shows different example signals over time, namely a signal IN provided at terminal 311 which indicates the state the transistor is intended to be in, Gᵢₙ, i.e. the signal at gate terminal 36, Detect, i.e. the signal output by energy modulator 37 to control switch 38, the drain current I_{D}, and the fault signal output at terminal 313.

As can be seen in FIG. 3C, when the signal IN goes high indicating that the transistor 32 is to be switched on, Gᵢₙ rises through the operation of gate driver 31A or 31B. In the diagram of FIG. 3C, it is assumed that a short circuit condition exists. Therefore, when the transistor is switched on, the current I_{D} rises sharply. When I_{D} exceeds a threshold current I_{SC}, this indicates an overcurrent condition detected by energy modulator 37. As indicated by an arrow 320, in response to I_{D} exceeding the threshold I_{SC}, the signal Detect goes to high. This closes switch 38, and as indicated by an arrow 321 the voltage at Gᵢₙ is reduced to the clamping voltage V_{clamp}, below the threshold V_{SC}. Furthermore, in response to I_{D} exceeding I_{SC}, energy modulator 37 sets transistor 32 to an overcurrent protection state, as explained above, which in the example of FIG. 3C prevents the current I_{D} from rising further, and in the example shown reduces the current again.

When Gᵢₙ falls below V_{SC}, this is detected using comparator 312, and as indicated by an arrow 322 the fault signal goes to high. Optionally, a system therefore may set the signal IN, i.e. the intended state of the transistor, to low, and as indicated by arrow 324 Gᵢₙ goes to low in response thereto.

In other embodiments, driver 31a, 31b itself may set Gᵢₙ to low directly or after a predefined waiting time.

In this respect, in embodiments where energy modulator 37 decouples the gate node of transistor 32 from gate terminal 36 when setting transistor 32 to an overcurrent protection state, this may be done using a unidirectional switch. Such a unidirectional switch may be implemented by a MOSFET having a body diode and, when open (e.g. MOSFET switched off) may prevent charging of the gate node of transistor 32 to switch transistor 32 fully on or keep transistor 32 fully on, but may allow discharging of the gate to switch transistor 32 off. Therefore, setting Gᵢₙ to low can affect the gate node of transistor 32 also in such an overcurrent protection state, for example pull it to lower voltages to fully switch transistor 32 off if energy modulator 37 only reduces the voltage to reduce the saturation current.

As can be seen, when the transistor is switched on Gᵢₙ rises and at first is also below V_{SC}. Therefore, in embodiments a blanking time 325 is used corresponding to the time the gate control signal requires to reach a high level after the signal IN goes to high, to prevent a false fault detection.

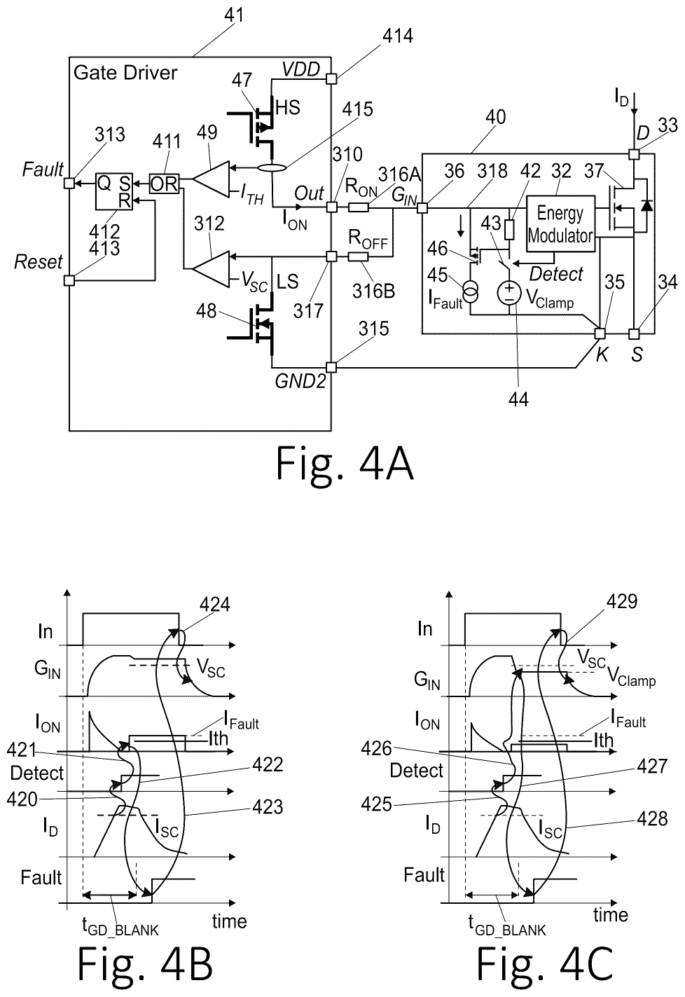

FIG. 4A is a system according to a further embodiment, which is an extension and a modification of the system of FIG. 3B, and corresponding elements bear the same reference numerals and will not be described again.

The system of FIG. 4A comprises a transistor module 40 and a driver 41. Transistor module 40 comprises a first signaling path coupled between control terminal 36 and auxiliary terminal 35 and configured to reduce the voltage at control terminal 36, and a second signaling path controlled by a node of the first signaling path and configured to sink the current from control terminal 36.

In the particular implementation shown, transistor module 40 includes a resistor 42 or other current limiting element and a switch 43 coupled between gate path 318 and auxiliary terminal 35. When energy modulator 37 detects the overcurrent condition, the signal Detect closes switch 43, which may set in some conditions described below the voltage at gate terminal 36 to V_{clamp}, as indicated by a voltage source 44. Resistor 42, switch 43 and voltage source 44 are an implementation example for the first signaling part mentioned above. Furthermore, a node between resistor 42 and switch 43 controls a transistor 46, which, when switched on, couples gate path 318 to auxiliary terminal 35 via a current source 45, to draw a fault current I_{fault}. Current source 45 and transistor 46 are an implementation example for the second signaling path mentioned above.

Gate driver 41 similar to the gate driver 31B of FIG. 3B includes two driver output terminals 310, 317, driver output terminal 310 for switching transistor 32 on and driver output terminal 317 for switching transistor 32 off. For generating a signal switching transistor 32 on, a high-side switch transistor 47 may couple driver output terminal 310 to a positive supply voltage VDD provided at a terminal 414, and for switching transistor 32 off, a low-side switch transistor 48 couples driver output terminal 317 to terminal 315 connected to auxiliary source terminal 35 as shown. Switches 47, 48 may be controlled based on an input signal IN (not shown in FIG. 4A, see FIGS. 3A and 3B) in a conventional manner, such that always only one of switch transistor 47, 48 is switched on, depending on whether transistor 32 is to be switched on or off.

Overcurrent detection in driver 41 may be based either on the voltage at terminal 36 being drawn to the clamping voltage Vclamp or based on the fault current Ifault drawn from terminal 36. Together with the resistor 42 (or more general: a current limiting element), voltage source 44 will limit the minimal voltage at gate terminal 36 to V_{clamp}+Vth, where Vth is the threshold voltage of the transistor 46. Resistor 42 limits the current such that the current drawn via resistor 42 and switch 43 (when closed) is lower, e.g. orders of magnitude lower, than Ifault and thus does not significantly affect current signaling.

Which detection mechanism is used may depend on a magnitude of Rₒₙ, i.e. the resistance of gate resistor 316A. If Rₒₙ is relatively high, the voltage at gate terminal 36 may be drawn to V_{clamp} by closing switch 43. This may then be detected by comparator 312, as explained with reference to FIGS. 3A and 3B. Like FIG. 3B, in FIG. 4A comparator 312 is coupled to driver output terminal 317. In other embodiments, comparator 312 may be coupled to a Miller clamp terminal or a separate sense terminal, as explained with reference to FIG. 3A.

If Rₒₙ is low or in other words the gate driving strength of gate driver 41 acting on gate terminal 36 is high, it may be difficult to draw the voltage at terminal 36 to V_{clamp}. In this case, however, when switch 43 closes the voltage at the gate of transistor 46 turns transistor 46 on, such that the fault current I_{fault} is drawn by current source 45. This current may be measured by a current measurement device 415 coupled between high-side switch transistor 47 and driver output terminal 310. The placement of current measurement device 415 may vary as long as the current through transistor 47 or the current flowing from terminal 414 to terminal 310 is measured. For example, current measurement device may also be placed between terminal 414 and transistor 47, or a sense cell measuring the current through transistor 47 may be used. The measured current is compared to a threshold current I_{TH}, and if the measured current exceeds the threshold current, comparator 49 detects a signaled overcurrent condition.

To quantify this, or products Ron×I_{fault}>=VDD−V_{clamp} the voltage at gate terminal 36 will drop to V_{clamp} (or VClamp+Vth of transistor 46), where Ron is the resistance of resistor 316A and VDD is the voltage at terminal 414. For products Ron×I_{fault}<VDD−V_{clamp}, i.e. for small Ron, the voltage at gate terminal 36 will be VGIN=VDD−Ron×I_{fault}.

An internal resistance of the driver (e.g. of transistor 47) is neglected in this consideration and for a more precise calculation may be added to the value of Ron.

The results of comparators 49 and 312 are combined in an OR gate 411, which means that if one of the comparators 49, 312 detects an overcurrent signaling, an overcurrent signaling is detected. The result of OR gate 411 is provided to terminal 313 via a latch 412, such that the fault signal is maintained once an overcurrent is detected. Latch 412 may be reset via a reset terminal 413. Other logic circuits combining the outputs of comparators 49 and 312 may also be used.

FIGS. 4B and 4C show the two cases of detection in FIG. 4A using example signals. FIG. 4B shows an example for a low resistive gate driver, for example low value of Rₒₙ. In addition to the quantities of FIG. 3C, also a current Iₒₙ is shown flowing from driver output terminal 310, i.e. the current measured by current measurement device 415.

The general situation is the same as in FIG. 3C, i.e. an input signal IN indicates that the transistor 32 is to be switched on, in the presence of some short circuit condition. For charging the gate, a comparatively high current Iₒₙ needs to flow. The current I_{D} rises until (similar to what has been explained for FIG. 3C) it exceeds the threshold I_{SC}, indicating an overcurrent. As indicated by an arrow 420, then the Detect signal is asserted, closing switch 43. As indicated by an arrow 421, this leads to the current Iₒₙ reaching I_{fault} through current source 45, as explained. This leads in turn, as indicated by arrow 422, to the fault signal being asserted, which in turn causes the system to set the signal In to low, which ultimately leads to the gate voltage level Gᵢₙ dropping, as indicated by arrow 424. Note that due to the low gate resistance and high gate driver strength, in this case Gᵢₙ does not fall below V_{SC}.

FIG. 4C shows the case for a high gate resistance. This essentially corresponds to the case of FIG. 3C. As indicated by an arrow 425, when the current I_{D} exceeds the threshold I_{SC}, the Detect signal closes switch 43. In this case, this draws the voltage Gᵢₙ below the threshold V_{SC}, thus leading to a fault detecting.

This is symbolized by arrow 426. As symbolized by arrow 427, this leads to assertion of the fault signal and as indicated by arrow 428, 429 again to the switching off of the transistor and corresponding fall of Gin. Please note that in this case Iₒₙ does not reach I_{fault}, such that the detection is only via comparator 312.

In both FIGS. 4B and 4C, a blanking time t_{GD_BLANK} is used (similar to blanking time 325 of FIG. 3C) before detection happens. As seen in FIGS. 4B and 4C, while switching transistor 47 on both the current Iₒₙ exceeds I_{fault}, and also the voltage Gᵢₙ initially is below V_{clamp}, such that without the blanking time here an erroneous detection of an overcurrent could occur.

In FIG. 4A, a particular implementation of the first and second signaling paths is shown, but other implementations are possible. For example, resistor 42 may be omitted, and a switching mechanism may be provided selectively coupling the gate terminal of transistor 46 to its source (i.e. to gate path 318), thus turning transistor 46 off, or to voltage source 44, thus turning transistor 46 on, as long as the voltage at gate terminal 36 V_GIN is greater than V_{clamp}−Vth, where Vth again is the threshold voltage of transistor 46.

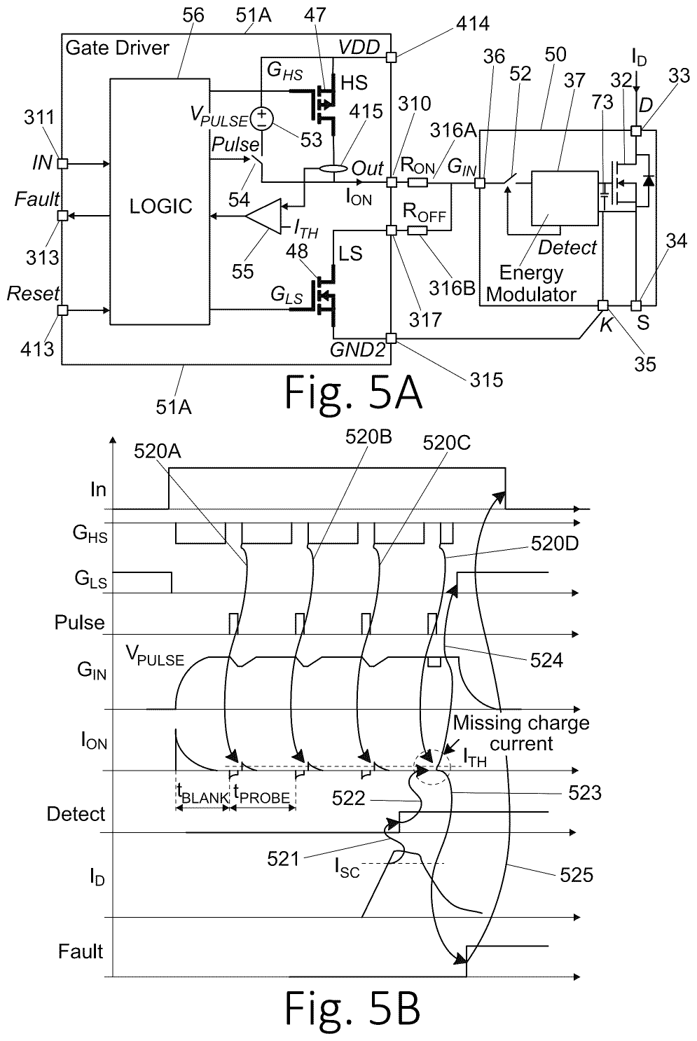

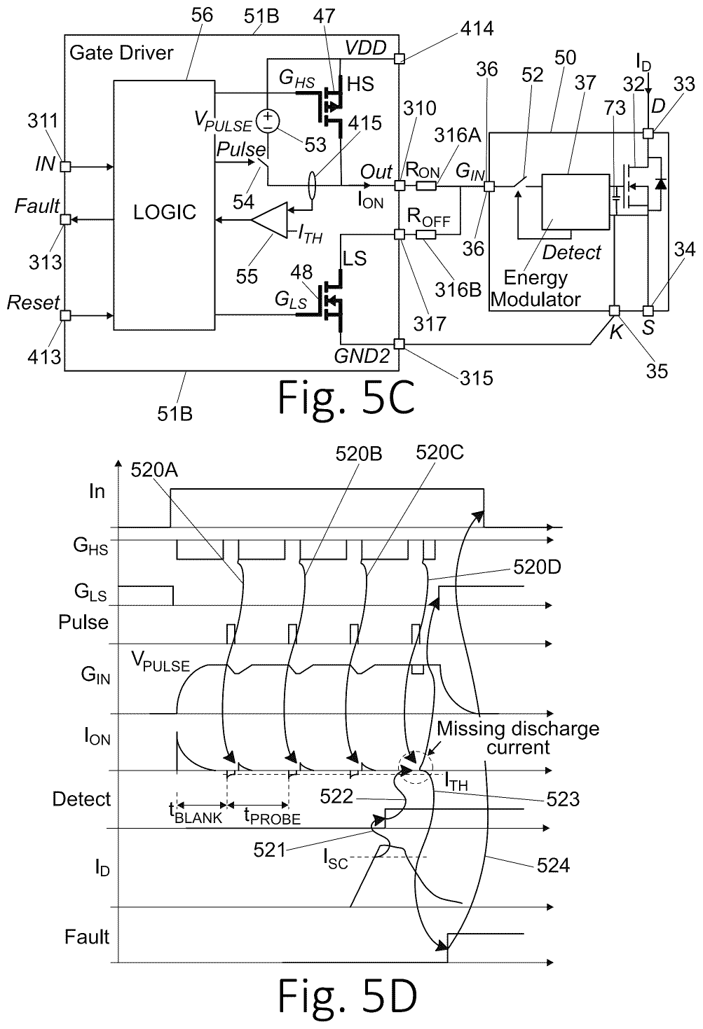

In the embodiments discussed above, a signaling circuit (for example 112 in FIG. 1, switch 38 in FIGS. 3A, 3B, elements 42 to 46 in FIG. 4A) signals a detected short circuit to gate driver. In embodiments discussed next with reference to FIGS. 5A to 5D, the gate driver transmits probe pulses to detect the short circuit condition.

FIG. 5A illustrates a system according to a further embodiment, including a transistor module 50 and a gate driver 51A. In transistor module 50, upon detecting a short circuit condition energy modulator 37 opens a switch 52 to disconnect gate terminal 36 from the gate node of transistor 32. It should be noted that in some embodiments there still may be a connection between gate terminal 36 and energy modulator 37 to supply energy modulator 37 with power. Furthermore, as mentioned above switch 52 may be a unidirectional switch, e.g. a MOSFET having a body diode, allowing to discharge the gate node of transistor 32 even when switch 52 is opened. Additionally, as explained previously, energy modulator 37 may change the voltage at the gate node, for example by coupling the gate node to the source node or another fixed voltage lower than VDD, to reduce the saturation current of transistor 32 or to switch transistor 32 off.

Opening of switch 52 has the consequence that the parasitic capacitances like gate source capacitance of transistor 32 (shown as capacitance 73 having a capacitance C_{IN}) is no longer “seen” at gate terminal 36. If a connection between gate terminal 36 and energy modulator 37 is maintained, an input capacitance of energy modulator 37 is still “seen”, but it is usually significantly smaller than the gate source capacitance of transistor 32. This is used for probing by gate driver 51A.

Driver 51A comprises a logic circuit 56 controlling the functions of driver 51A. Such a logic circuit controlling the correspondingly described functions of the respective driver may also be provided in the previous embodiments. During normal operation, logic circuit 56 receives the input signal IN at terminal 311 and controls high-side switch transistor 47 and low-side switch transistor 48 using corresponding gate signals G_{HS}, G_{LS}, respectively to switch transistor 32 on and off. In addition, when transistor 32 is to be switched on, i.e. high-side switch transistor 47 is switched on to provide a corresponding gate control signal at terminal 310, the gate control signal is modulated by a pulsed voltage controlled by logic 56. In FIG. 5A, this is symbolized by a switch 54 which is opened and closed to generate pulses with a pulse voltage symbolized by voltage source 53. These pulses lead to a modulation of the current Iₒₙ, which may be measured. Instead of adding voltage pulses, in the embodiment of FIG. 5A also a current modulation may be used where a current source pulls a current from node 310. The modulation changes when switch 52 is opened in response to a short circuit.

In FIG. 5A, the on current is measured as the current flowing through high-side switch transistor 47 when transistor 47 is turned on again by current measurement device 415 and compared to a threshold current by comparator 55. The detection of an overcurrent condition by gate driver 51A in this case is illustrated in FIG. 5B. In FIG. 5B, it is assumed when the transistor is switched on, no short circuit is present, but the short circuit occurs only later.

In FIG. 5B, the same signals as in FIGS. 4B and 4C are depicted. Additionally, signals G_{HS}, G_{LS}, and Pulse (the signal controlling switch 54) are shown in FIG. 5B.

In FIG. 5B, when the signal IN indicates that transistor 32 is to be switched on, low-side switch transistor 48 is switched off (G_{LS} goes low), and high-side switch transistor 47 is switched on by signal G_{HS}. are shown. After a blanking time T_{blank}, pulses are generated by modulating G_{HS} with V_{Pulse} of voltage source 53, corresponding to the closing of switch 54. At the end of the pulses as indicated by arrows 520A to 520C, the current Iₒₙ as measured by current sensor 415 exceeds the threshold current I_{TH} (comparison by comparator 55), which in this case indicates that no short circuit has been detected by energy modulator 37, and switch 52 is closed. The short interruption of G_{HS} in this case as shown for Iₒₙ leads to a slight discharging of the gate-source capacitance followed by a slight charging, during which I_{TH} is exceeded.

Then, a short circuit occurs, and I_{D} exceeds I_{SC}, as discussed previously. As indicated by an arrow 521, the signal Detect is asserted, opening switch 52 of FIG. 5A. During a next pulse, as indicated by arrow 520D, therefore transistor 32 is decoupled from gate terminal 36, and the gate is not discharged by the pulse and not charged again afterwards. Therefore, in this case the charge current is very low (referred to as “missing” in FIG. 5B) and in any case does not exceed I_{TH}. This in turn, as indicated by an arrow 523, leads to assertion of the fault signal. Additionally, as indicated by an arrow 525, logic 56 switches low-side switch transistor 48 on and high-side switch transistor 47 off. Optionally, following the communication of the fault signal to a system entity, as indicated by arrow 525 also the signal IN may then be set to low indicating that the transistor is to be switched off.

In FIGS. 5A and 5B, the overcurrent condition is thus detected by observing the missing charge current. Alternatively, the detection may also be made by detecting the missing discharge current. This is illustrated in FIGS. 5C and 5D. FIG. 5C illustrates a system according to an embodiment, where compared to the system of FIG. 5A instead of driver 51A a driver 51B is provided. The only difference to driver 51A is the placement of current sensor 415 as shown. With this placement, the discharge current may be observed. This is illustrated in FIG. 5D, which, including the arrows, essentially corresponds to FIG. 5B. The difference is here that the low (“missing”) discharge current, i.e. discharge current lower than a threshold, at the pulse corresponding to arrow 520D is detected and not the missing charge current. In still other embodiments, both detections may be used to provide redundancy.

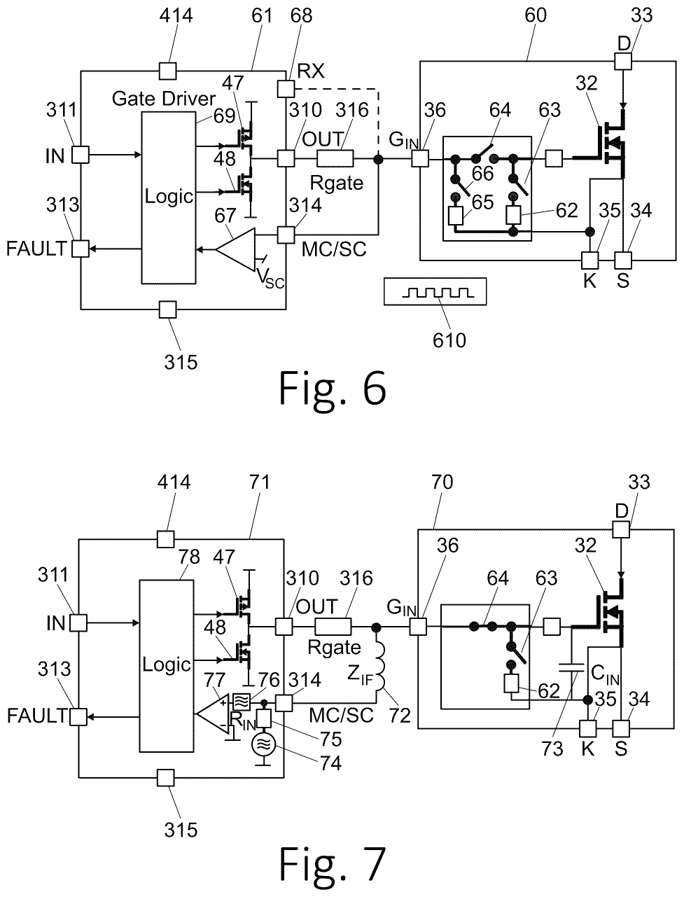

FIG. 6 illustrates a further system according to an embodiment. The system of FIG. 6 comprises a transistor module 60 and a gate driver 61.

In the example of FIG. 6, a single driver output terminal 310 is used, but also two separate gate driver outputs as in FIG. 3B, 4A or 5A and 5C may be used, or vice versa, i.e. also in FIG. 3B, 4A, 5A or 5C an single gate driver output may be used.

Transistor module 60 includes an overcurrent protection circuit of which switches 63, 64 are shown. During normal operation, switch 64 is closed coupling gate terminal 36 to the gate node of transistor 32, and switch 63 is open. In this case, in gate driver 61 a high-side switch transistor 47 and low-side switch transistor 48 may be provided in a half-bridge configuration as shown to control output terminal 310, controlled by logic 69. As described also for logic 56 of FIG. 5A, during normal operation logic circuit 69 may control switch transistors 47, 48 depending on input signal IN.

When transistor module 60 detects a short circuit, switch 64 is opened decoupling gate terminal 36 from the gate node of transistor 32. Moreover, switch 63 is closed coupling the gate node of transistor 32 to the source node of transistor 32 via a resistor 62, thus at least partially switching transistor 32 off by pulling the gate voltage towards the source voltage. Alternatively, the gate node of transistor may be pulled to a lower voltage to reduce a saturation current without fully switching transistor 32 off.

In addition, for signaling, transistor module 60 includes a switch 66 coupled between gate terminal 36 and auxiliary source terminal 35 via a resistor 65. When transistor module 60 detects an overcurrent, switch 66 is repeatedly opened and closed, to generate a modulated signal as schematically shown as signal 610. The repeatedly opening and closing may be according to a predefined pattern, for example with a fixed frequency or also with a variable frequency. This signal may be detected by a comparator 67 of driver 61 comparing the voltage at gate terminal 36 to a threshold voltage V_{SC}, when the modulated signal toggles between a value above the threshold V_{SC} and below the threshold. While a Miller clamp input 314 is used for sensing in FIG. 6, an additional sensing terminal 68 may also be used alternatively.

A typical pulse duration of the modulated signal may be between 200 ns and 5 μs, which may correspond to a frequency of at least 100 kHz or more. The current level through closed switch 66 in this case may be in the range of milliamperes or some ten milliamperes, sufficient to charge and discharge any stray capacitances at terminal 36 even at such frequencies. In other embodiments, the current caused by the toggling may be detected similar to the current sensing shown in FIG. 4A.

Also, a current mirror may be used mirroring the current flowing when opening and closing witch 66, and the mirrored current may be measured. For detection, in some embodiments, a high pass filter adapted to the toggling frequency of switch 66 may be used.

FIG. 7 illustrates a further system, which is a variation of the system of FIG. 6. The system of FIG. 7 comprises a transistor module 70 and a gate driver 71. Compared to transistor module 60, in transistor module 70 switch 66 is omitted. Similar to the embodiment of FIGS. 5A and 5C, detection in the embodiment of FIG. 7 is based on the fact that an input capacitance of transistor 32, here shown as capacitance 73, is decoupled from gate terminal 36 by opening switch 64 in case of an overcurrent.

In the system of FIG. 7, for probing driver circuit 71 injects a high frequency probe signal. In normal operation, this high frequency probe signal sees the wiring impedance 72, also labeled Z_{IF}, provided by the wiring between gate driver 71 and transistor module 70, and as termination capacitance 73. In case of a fault, this termination is removed, leading to a significant higher voltage at a corresponding measurement pin, in the example of FIG. 7 Miller clamp input 314, although a separate measurement pin or a gate driver output for turn-off as discussed previously may be used. The high frequency probe signal is generated by a signal generator 74 via a resistor 75 and controlled by a logic 78.

The detection is using a high-pass filter 76 and a comparator 77. Also in this way, using a high frequency probe signal the overcurrent condition may be detected.

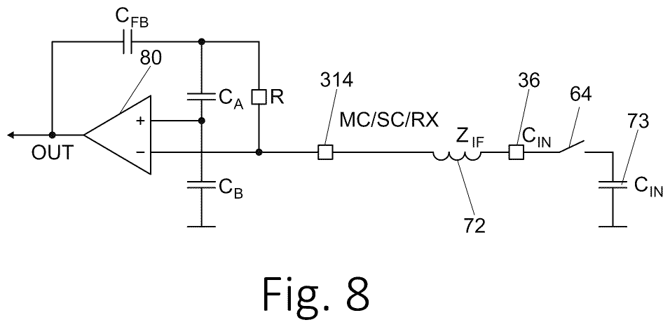

In another embodiment, impedance 72 and capacitance 73 determine a resonance frequency, for example of an astable multivibrator realized in the driver. This multivibrator is only activated during a static turning on of the transistor 32. An example is shown in FIG. 8, where a multivibrator comprises an amplifying element 80, a feedback capacitor C_{FB}, capacitors C_{A}, C_{B} and resistor R. When switch 64 is opened, capacitor 73 is disconnected, thus changing the frequency of the multivibrator. In case switch 64 is opened, capacitance 73 is disconnected and the resonance frequency changes, which may be detected.

In embodiments like the one of FIG. 7, an initial calibration may be performed for example to determine a suitable threshold value for comparator 77 or to determine an initial oscillation frequency.

Some embodiments are defined by the following examples:

Example 1. A transistor module, comprising:
a transistor, wherein a first load node of the transistor is coupled to a first load terminal of the transistor module, a second load node of the transistor is coupled to a second load terminal of the transistor module, and wherein a control path is coupled between a control node of the transistor and a control terminal of the transistor module,
an overcurrent protection circuit configured to detect an overcurrent condition of the transistor and to set the transistor to an overcurrent protection state in response to detecting the overcurrent condition, and a signaling circuit coupled to the control terminal and configured to modify a signal level at the control terminal in response to the overcurrent protection circuit detecting the overcurrent condition.

Example 2. The transistor module of example 1,
wherein the control path comprises a first switch,
wherein setting the transistor to an overcurrent protection state comprises opening the first switch to decouple the control node from the control terminal.

Example 3. The transistor module of example 2, wherein the signaling circuit is coupled to a node of the control path between the control terminal and the first switch.

Example 4. The transistor module of any one of examples 1 to 3, wherein the signaling circuit is configured to reduce a voltage at the control terminal in response to the overcurrent protection circuit detecting the overcurrent condition.

Example 5. The transistor module of example 4, wherein the signaling circuit is configured to reduce the voltage at the control terminal to between 40% and 90% of a voltage at the control terminal in an on-state.

Example 6. The transistor module of any one of examples 1 to 5, wherein the signaling circuit is configured to sink a current from the control terminal in response to the overcurrent protection circuit detecting an overcurrent condition.

Example 7. The transistor module of any one of examples 1 to 6, wherein the transistor module comprises an auxiliary terminal coupled to the second load node of the transistor and configured to provide a return path for a driver, wherein the signaling circuit is coupled between the control terminal and the auxiliary terminal.

Example 8. The transistor module of example 4 or 5, of example 6 and of example 7, wherein the signaling circuit comprises a first signaling path coupled between the control terminal and the auxiliary terminal and a second signaling path controlled by a node of the first signaling path and configured to sink the current from the control terminal.

Example 9. The transistor module of any one of examples 1 to 8, wherein the signaling circuit is configured to generate a pulsed signal having a predefined pattern at the control terminal in response to the overcurrent protection circuit detecting the overcurrent condition.

Example 10. The transistor module of example 9, wherein the signaling circuit comprises a second switch, wherein the signaling circuit is configured for generating the pulsed signal having the predefined pattern by opening and closing the second switch in accordance with the predefined pattern.

Example 11. A driver for a transistor module, comprising:
a driver output terminal configured to be coupled to a control terminal of the transistor module,
driver circuitry configured to generate a control signal to be output at the driver output terminal,
a sense terminal configured to be coupled to the control terminal of the transistor module, and
a detection circuit configured to detect an overcurrent condition of the transistor module based on a signal at the sense terminal.

Example 12. The driver of example 11, wherein the driver output terminal comprises the sense terminal.

Example 13. The driver of example 12,
wherein the driver output terminal comprises a positive driver output terminal and a negative driver output terminal, wherein the sense terminal comprises the negative driver output terminal.

Example 14. The driver of example 11, wherein the sense terminal comprises a Miller clamp terminal.

Example 15. The driver of any one of examples 11 to 14,
wherein the detection circuit is configured to compare a current at the driver output terminal to a first threshold value to obtain a first comparison result, to compare a voltage at the sense terminal to a second threshold value to obtain a second comparison result, and to detect the overcurrent condition based on the first comparison result and the second comparison result.

Example 16. The driver of any one of examples 11 to 15,
wherein the detection circuit is configured to detect the overcurrent condition in response to detecting a pulsed signal having a predefined pattern at the sense terminal.

Example 17. The driver of any one of examples 11 to 16,
wherein the driver circuity is configured to output a probe signal to be provided to a control terminal of the transistor module,
wherein the detection circuit is configured to detect the overcurrent condition based on a response to the probe signal.

Example 18. The driver of example 17, wherein the response comprises one of a charge current or a discharge current being below a threshold.

Example 19. The driver of example 17 or 18, wherein the probe signal is a pulsed signal.

Example 20. A system, comprising:
the transistor module of any one of examples 1 to 10, and
the driver of any one of examples 11 to 19,
wherein the driver output terminal of the driver is coupled to the control terminal of the transistor module via a gate resistor.

Example 21. A method, comprising:
at a transistor module:
   detecting an overcurrent condition of a transistor of the transistor module,
   setting the transistor to an overcurrent protection state, and
at a driver coupled to a control terminal of the transistor module, detecting the overcurrent condition based on a signal level at the control terminal.

Example 22. The method of example 21, wherein setting the transistor to an overcurrent protection state interrupting a control path between the control terminal and a control node of the transistor.

Example 23. The method of example 22, wherein the method further comprises, at the transistor module, modifying a signal at the control terminal in response to detecting the overcurrent condition, wherein the detecting the overcurrent condition at the driver comprises detecting the modified signal.

Example 24. The method of example 23, wherein the modifying comprises at least one of drawing the signal to a voltage level lower than a voltage level in an on-state of the transistor or sinking a current from the control terminal.

Example 25. The method of example 24, wherein detecting the overcurrent condition at the driver comprises detecting either the drawing to the voltage level or the sinking of the current depending on a magnitude of a gate resistor between the driver and the transistor module.

Example 26. The method of example 22, wherein detecting the overcurrent condition at the driver comprises transmitting a probe signal from the driver to the control terminal and detecting the overcurrent condition based on a response to the probe signal.

Although specific embodiments have been illustrated and described herein, it will be appreciated by those of ordinary skill in the art that a variety of alternate and/or equivalent implementations may be substituted for the specific embodiments shown and described without departing from the scope of the disclosed subject matter. This application is intended to cover any adaptations or variations of the specific embodiments discussed herein. Therefore, it is intended that the disclosed subject matter be limited only by the claims and the equivalents thereof.

1. A transistor module, comprising:
a transistor, wherein a first load node of the transistor is coupled to a first load terminal of the transistor module, a second load node of the transistor is coupled to a second load terminal of the transistor module, and wherein a control path is coupled between a control node of the transistor and a control terminal of the transistor module;
an overcurrent protection circuit configured to detect an overcurrent condition of the transistor and to set the transistor to an overcurrent protection state in response to detecting the overcurrent condition; and
a signaling circuit coupled to the control terminal and configured to modify a signal level at the control terminal in response to the overcurrent protection circuit detecting the overcurrent condition.

2. The transistor module of claim 1,
wherein the control path comprises a first switch,
wherein setting the transistor to the overcurrent protection state comprises opening the first switch to decouple the control node from the control terminal.

3. The transistor module of claim 2, wherein the signaling circuit is coupled to a node of the control path between the control terminal and the first switch.

4. The transistor module of claim 1, wherein the signaling circuit is configured to reduce a voltage at the control terminal in response to the overcurrent protection circuit detecting the overcurrent condition.

5. The transistor module of claim 1, wherein the signaling circuit is configured to sink a current from the control terminal in response to the overcurrent protection circuit detecting the overcurrent condition.

6. The transistor module of claim 1, wherein the transistor module comprises an auxiliary terminal coupled to the second load node of the transistor and configured to provide a return path for a driver, wherein the signaling circuit is coupled between the control terminal and the auxiliary terminal.

7. The transistor module of claim 6, wherein the signaling circuit comprises a first signaling path coupled between the control terminal and the auxiliary terminal and a second signaling path controlled by a node of the first signaling path and configured to sink the current from the control terminal.

8. The transistor module of claim 1, wherein the signaling circuit is configured to generate a pulsed signal having a predefined pattern at the control terminal in response to the overcurrent protection circuit detecting the overcurrent condition.

9. A driver for a transistor module, comprising:
a driver output terminal configured to be coupled to a control terminal of the transistor module;
driver circuitry configured to generate a control signal to be output at the driver output terminal;
a sense terminal configured to be coupled to the control terminal of the transistor module; and
a detection circuit configured to detect an overcurrent condition of the transistor module based on a signal at the sense terminal.

10. The driver of claim 9,
wherein the detection circuit is configured to compare a current at the driver output terminal to a first threshold value to obtain a first comparison result, to compare a voltage at the sense terminal to a second threshold value to obtain a second comparison result, and to detect the overcurrent condition based on the first comparison result and the second comparison result.

11. The driver of claim 9,
wherein the detection circuit is configured to detect the overcurrent condition in response to detecting a pulsed signal having a predefined pattern at the sense terminal.

12. The driver of claim 9,
wherein the driver circuity is configured to output a probe signal to be provided to the control terminal of the transistor module,
wherein the detection circuit is configured to detect the overcurrent condition based on a response to the probe signal.

13. The driver of claim 12, wherein the response comprises one of a charge current or a discharge current being below a threshold.

14. A system for overcurrent protection, comprising:
the transistor module of claim 9, and
the driver of claim 9,
wherein the driver output terminal of the driver is coupled to the control terminal of the transistor module via a gate resistor.

15. A method for overcurrent protection, comprising:
at a transistor module:
detecting an overcurrent condition of a transistor of the transistor module; and
setting the transistor to an overcurrent protection state; and
at a driver coupled to a control terminal of the transistor module, detecting the overcurrent condition based on a signal level at the control terminal.

16. The method of claim 15, wherein setting the transistor to the overcurrent protection state interrupting a control path between the control terminal and a control node of the transistor.

17. The method of claim 16, wherein the method further comprises, at the transistor module, modifying a signal at the control terminal in response to detecting the overcurrent condition, wherein the detecting the overcurrent condition at the driver comprises detecting the modified signal.

18. The method of claim 17, wherein the modifying comprises at least one of drawing the signal to a voltage level lower than a voltage level in an on-state of the transistor or sinking a current from the control terminal.

19. The method of claim 18, wherein detecting the overcurrent condition at the driver comprises detecting either the drawing to the voltage level or the sinking of the current depending on a magnitude of a gate resistor between the driver and the transistor module.

20. The method of claim 16, wherein detecting the overcurrent condition at the driver comprises transmitting a probe signal from the drive to the control terminal and detecting the overcurrent condition based on a response to the probe signal.
